(19) United States
(12) Patent Application Publication
(10) Pub. No.: US 2014/0361407 A1
(43) Pub. Date: Dec. 11, 2014

(54) SILICON MATERIAL SUBSTRATE DOPING METHOD, STRUCTURE AND APPLICATIONS

(71) Applicants: SCHMID Group, Freudenstadt (DE); University of Central Florida Research Foundation Inc., Orlando, FL (US)

(72) Inventors: Kristopher O. Davis, Orlando, FL (US); Winston V. Schoenfeld, Oviedo, FL (US); Kaiyun Jiang, Freudenstadt (DE); Dirk Habermann, Freudenstadt (DE)

(73) Assignees: SCHMID Group, Freudenstadt (DE); University of Central Florida Research Foundation Inc., Orlando, FL (US)

(21) Appl. No.: 13/910,310

(22) Filed: Jun. 5, 2013

(51) Int. Cl. H01L 21/225; H01L 29/06

(52) U.S. Cl. CPC H01L 21/2255; H01L 29/0603
USPC 257/607; 438/563

(57) ABSTRACT

A method for forming a boron doped region within a silicon material substrate, and the resulting silicon material substrate that includes the boron doped region, each use a boron doped aluminum oxide material layer as a boron dopant source layer. The method provides the boron doped region with a sheet resistance in a range from about 15 to about 300 ohms per square. The method is also applicable, in general, to forming an n doped region, a p doped region or an n and p co-doped region within a silicon material substrate.

### BACKGROUND

1. Field of the Invention

Embodiments relate generally to doped silicon material substrates. More particularly embodiments relate to doping of silicon material substrates which may optionally additionally include a background doping such as a p-type background doping or an n-type background doping.

2. Description of the Related Art

Regionally selective and regionally non-selective doping of silicon material substrates is known in relevant arts such as but not limited to the microelectronic, optoelectronic and photovoltaic arts, in order to fulfill electrical performance characteristics of desirable microelectronic, optoelectronic and photovoltaic structures. Insofar as microelectronic, optoelectronic and photovoltaic arts continue to evolve, desirable are improved methods for doping silicon material substrates used in the microelectronic, optoelectronic and photovoltaic arts.

### SUMMARY

Embodiments provide a doping method (i.e., preferably but not limited to a p doping method) for forming a doped structure (i.e., preferably but not limited to a p doped structure) within a silicon material substrate, as well as the silicon material substrate within which is located and formed the doped structure that is formed using the method in accordance with the embodiments.

The preferable p doping method in accordance with the embodiments in particular uses a boron doped aluminum oxide material layer as a p dopant diffusion source layer, and under appropriate circumstances also as a passivation layer, when forming the p doped structure within the silicon material substrate. In comparison with a boron doped silicon oxide material layer as a p dopant diffusion source layer, the boron doped aluminum oxide material layer provides for improved properties of the p doped structure. Such improved properties may include, but are not necessarily limited to: (1) a reduced sensitivity to oxygen during drive-in diffusion (thus allowing for simplified processing and the use of a thinner, if any, capping layer, thus providing improved optical properties within a resulting structure); and (2) an increased minority carrier lifetime following diffusion (i.e., greater than 500 micro seconds, as may be demonstrated with a 90 ohms per square sheet resistance), thus allowing for simultaneous doping and surface passivation in one process step. Additionally, due to the lower sensitivity to oxygen during drive-in diffusion, the boron doped aluminum oxide material layers in accordance with the embodiments may under appropriate circumstances be diffused without the use of an additional capping layer (e.g. SiO₂ or other silicon oxide material).

A particular method in accordance with the embodiments includes forming a doped aluminum oxide material layer upon a silicon material substrate. This particular method also includes thermally annealing the doped aluminum oxide material layer formed upon the silicon material substrate to form a dopant depleted doped aluminum oxide material layer upon a silicon material substrate that includes a doped region.

Another particular method in accordance with the embodiments includes forming a boron doped aluminum oxide material layer upon a silicon material substrate. The particular method also includes thermally annealing the boron doped aluminum oxide material layer formed upon the silicon material substrate to form a boron depleted boron doped aluminum oxide material layer upon a silicon material substrate that includes a boron doped region.

A particular structure in accordance with the embodiments includes a silicon material substrate. This particular structure also includes a doped region located within the silicon material substrate. This particular structure also includes a doped aluminum oxide material layer located over the silicon material substrate and contacting the boron doped region, where the doped region and the doped aluminum oxide material layer comprise the same dopant.

Another particular structure in accordance with the embodiments includes a silicon material substrate. This particular structure also includes a boron doped region located within the silicon material substrate. The particular structure also includes a boron doped aluminum oxide material layer located over the silicon material substrate and contacting the boron doped region.

Within the embodiments, use of the terminology “over” within the context of a first layer or structure with respect to a second layer or a structure is intended to indicate a relative vertical and overlapping disposition of the first layer or structure with respect to the second layer or structure, but not necessarily contact of the first layer or structure with the second layer or structure. In contrast, within the embodiments, use of the terminology “upon” within the context of one layer or structure with respect to another layer or structure is intended to indicate the same type of relative vertical and overlapping disposition of the first layer or structure with the second layer or structure, but with contact between the first layer or structure and the second layer or structure.

### BRIEF DESCRIPTION OF THE DRAWINGS

The objects, features and advantages of the embodiments are understood within the context of the Detailed Description of the Embodiments, as set forth below. The Detailed Description of the Embodiments is understood within the context of the accompanying drawings, that form a material part of this disclosure, wherein:

FIG. 1 shows: (a) a blanket boron dopant diffusion; and (b) a selective boron dopant diffusion, into a silicon material substrate to form a boron p doped region within the silicon material substrate, in accordance with the embodiments.

FIG. 2 shows a secondary ion mass spectroscopy (SIMS) spectrum illustrating boron p doped region diffusion depth profile into a silicon material substrate in accordance with the embodiments.

### DETAILED DESCRIPTION OF THE EMBODIMENTS

Embodiments provide a method for forming a doped structure (i.e., particularly but not limited to a p doped structure) within a silicon material substrate, as well as the silicon material substrate that includes the doped structure (i.e., particularly but not limited to the p doped structure) located and formed therein in accordance with the embodiments. Thus, the embodiments also contemplate n doped structures and p/n co-doped structures formed in accordance with analogous methods in accordance with the embodiments with respect to p doped structures.

The p doping method in particular uses a boron doped aluminum oxide material layer as a p dopant diffusion source layer to provide the silicon material substrate that includes the p doped structure that has: (1) a highly controllable sheet resistances within a range from about 15 to about 300 ohms per square; and (2) a minority carrier lifetime in excess of 500 microseconds on high-quality monocrystalline silicon wafers (e.g., for a doping level corresponding with a 90 ohms per square sheet resistance).

The p doping, n doping and p and n doping methods in accordance with the embodiments in general use an aluminum oxide material layer that may include a p dopant (i.e., such as but not limited to boron), or alternatively an n dopant (i.e., such as but not limited to phosphorus or arsenic). Further alternatively, the p and n doping method in accordance with the embodiments may use at least one p dopant and at least one n dopant selected from the foregoing p dopant and n dopants. Within any of the foregoing embodiments, the p or n doped aluminum oxide material layer has a thickness from about 10 to about 40 nanometers and a p and/or n dopant concentration from about 1 to about 25 atomic percent, as indicated below.

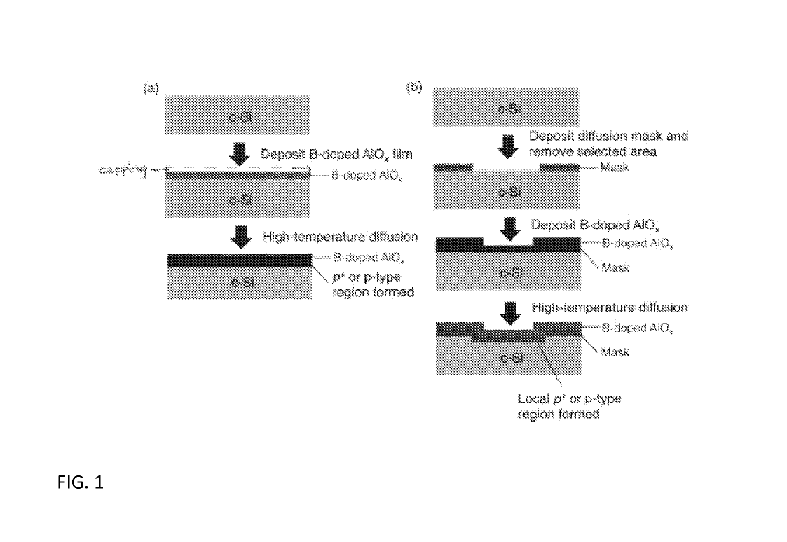

FIG. 1A and FIG. 1B show a pair of series of schematic cross-sectional diagrams illustrating the results of progressive process steps in forming a p doped structure (i.e., p doped region) within a silicon material substrate in accordance with the embodiments. FIG. 1A shows a blanket p doped structure (i.e., p doped region) within a silicon material substrate while FIG. 1B shows a selective or localized p doped structure (i.e., p doped region) within a silicon material substrate.

FIG. 1A, first diagram, first illustrates a silicon material substrate. Although not specifically limiting to the embodiments, the silicon material substrate is intended as a crystalline silicon material substrate, and in particular a monocrystalline silicon material substrate. Such a monocrystalline silicon material substrate may comprise any of several crystallographic orientations as are otherwise generally known and generally desirable within the context of specific applications within which are employed the monocrystalline silicon material substrate.

Such crystallographic orientations may include, but are not necessarily limited to 111, 100, 110, and 001 crystallographic orientations. As well, the silicon material substrate may also be provided with a background dopant of either an n-type or a p-type to provide the silicon material substrate with a bulk wafer resistivity from about 0.5 to 500 ohm-cm.

Similarly, while the embodiments illustrate the invention within the context of a monocrystalline silicon substrate, the embodiments also contemplate applicability within the context of substrates comprising in general semiconductor materials that are silicon containing. These additional silicon containing materials may include, but are not necessarily limited to, multicrystalline silicon, silicon-carbon alloy materials and silicon-germanium alloy materials.

Most typically and preferably the embodiments contemplate a silicon material substrate that comprises a pure monocrystalline silicon material substrate that includes any of the several crystallographic orientations that are listed above.

FIG. 1A, second diagram, illustrates a boron doped aluminum oxide material layer located and formed upon the silicon material substrate. FIG. 1A, second diagram, also illustrates an optional capping layer in phantom located and formed upon the boron doped aluminum oxide material layer.

Desirably, within the context of the embodiments, the boron doped aluminum oxide material layer is formed to a thickness from about 10 to about 40 nanometers upon the silicon material substrate. Also desirable, within the context of the embodiments, the boron doped aluminum oxide material layer has a boron atomic percent dopant concentration from about 1 to about 25 atomic percent, depending on a desired sheet resistance, as well as a desired diffusion time and a desired diffusion temperature. Additionally, the use of the capping layer, e.g. silicon oxide (or other appropriate dopant diffusion inhibiting capping material), with a uniform thickness of about 40 to about 100 nanometers can also be used located and formed upon the boron doped aluminum oxide material layer, to facilitate boron diffusion into the silicon material substrate. Although not necessarily limiting to the embodiments, the boron doped aluminum oxide material layer may be formed using an atmospheric pressure chemical vapor deposition (APCVD) method. Any of several alternative methods, including but not limited to other chemical vapor deposition methods, as well as physical vapor deposition methods, may also be used for forming the boron doped aluminum oxide material layer upon the silicon material substrate. As well, any of several methods, and additional materials as noted above, may also be used for forming the capping layer.

Typically, the atmospheric pressure chemical vapor deposition (APCVD) method with respect to forming the boron doped aluminum oxide material layer also uses: (1) a silicon material substrate temperature from about 330 to about 380 degrees centigrade; (2) a reactor chamber pressure at approximately 760 torr; (3) an aluminum source material flow rate from about 10 to about 30 standard cubic centimeters per minute; (4) an oxidant source material flow rate from about 0.5 to about 1.5 standard cubic centimeters per minute; and (5) a boron source material flow rate from about 0.1 to about 5 standard cubic centimeters per minute.

Typical but not limiting source materials may include, but are not necessarily limited to: (1) aluminum alkoxide aluminum source materials; (2) oxygen or ozone oxidant source materials; and (3) borane, diborane or boron trichloride boron source materials. Also contemplated within the context of the embodiments is the use of diluents and non-reactive carrier gasses. As is understood by a person skilled in the art, substitution of a boron source material with an alternative p dopant source material, or further alternatively an n dopant alone or with a p dopant source material, will provide alternative p doped structures, n doped structures and p and n doped structures in accordance with the embodiments.

FIG. 1A, third diagram, illustrates the results of a thermal annealing process step applied to the microelectronic structure of FIG. 1A, second diagram, where the microelectronic structure including the silicon material substrate having located and formed thereupon the boron doped aluminum oxide material layer is thermally annealed to provide the semiconductor structure of FIG. 1A, third diagram. The third diagram thus illustrates a boron depleted boron doped aluminum oxide material layer located and formed upon a silicon material substrate that now includes a boron doped region. The thermal annealing is undertaken at a temperature from about 800 to about 1100 degrees centigrade for a time period from about 15 to about 30 minutes to provide the boron dopant depleted boron doped aluminum oxide material layer, as well as the boron doped region within the silicon material substrate.

The series of schematic cross sectional diagrams that is illustrated in FIG. 1B follows generally from the series of schematic cross-sectional diagrams that is illustrated in FIG. 1A but also newly includes a mask layer selectively interposed between the silicon material substrate and the boron doped aluminum oxide material layer. Such a mask layer generally provides for formation of a localized boron doped region within the silicon material substrate (as illustrated in FIG. 1B, fourth diagram) rather than a blanket boron doped region within the silicon material substrate (as illustrated in FIG. 1B, third diagram). Although a mask layer may in general comprise any of several mask materials, such as but not limited to hard mask materials and soft mask materials, within the context of the embodiments the mask layer typically comprises a temperature insensitive hard mask material such as but not limited to a silicon nitride, silicon oxynitride or titanium oxide hard mask material. Typically, the mask layer comprises a titanium oxide hard mask material that has a thickness from about 50 to about 100 nanometers.

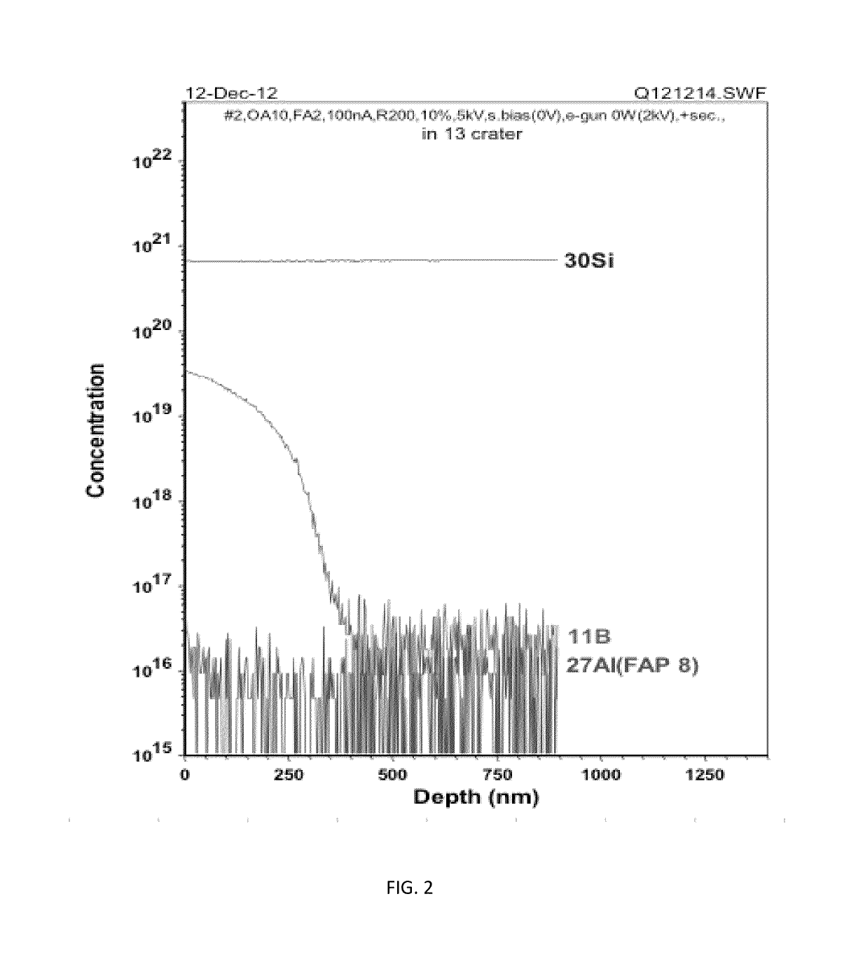

FIG. 2 shows a graph illustrating a dopant depth profile within a monocrystalline silicon substrate for forming a boron p doped region in accordance with the embodiments. Also illustrated for reference purposes is a silicon concentration and a aluminum background concentration. As is illustrated within the schematic diagram of FIG. 2, the boron concentration decreases to a background level at a depth of about 400 nanometers.

The graph of FIG. 2 results from a monocrystalline silicon material substrate having located and formed thereupon a boron doped aluminum oxide material layer of thickness about 20 nanometers and a boron content about 20 atomic percent. Additionally, a silicon oxide capping layer of about 80 nanometers was deposited onto the boron doped aluminum oxide material layer to facilitate diffusion of boron into the monocrystalline silicon material substrate. The monocrystalline silicon material substrate and the boron doped aluminum oxide material layer were thermally annealed at a temperature of about 945 degrees centigrade for a time period of about 40 minutes to provide a resulting structure whose depth profiling graph is illustrated in FIG. 2.

All references, including publications, patent applications, and patents cited herein are hereby incorporated by reference in their entireties to the same extent as if each reference was individually and specifically indicated to be incorporated by reference and was set forth in its entirety herein.

The use of the terms “a” and “an” and “the” and similar referents in the context of describing the invention (especially in the context of the following claims) is to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening.

The recitation of ranges of values herein are merely intended to serve as a shorthand method of referring individually to each separate value falling within the range, unless otherwise indicated herein, and each separate value is incorporated into the specification as if it was individually recited herein.

All methods described herein can be performed in any suitable order unless otherwise indicated herein or otherwise clearly contradicted by context. The use of any and all examples, or exemplary language (e.g., “such as”) provided herein, is intended merely to better illuminate embodiments of the invention and does not impose a limitation on the scope of the invention unless otherwise claimed.

No language in the specification should be construed as indicating any non-claimed element as essential to the practice of the invention.

It will be apparent to those skilled in the art that various modifications and variations can be made to the present invention without departing from the spirit and scope of the invention. There is no intention to limit the invention to the specific form or forms disclosed, but on the contrary, the intention is to cover all modifications, alternative constructions, and equivalents falling within the spirit and scope of the invention, as defined in the appended claims. Thus, it is intended that the present invention cover the modifications and variations of this invention provided they come within the scope of the appended claims and their equivalents.

Thus, the embodiments are illustrative of the invention rather than limiting of the invention. Revisions and modifications may be made to methods, materials structures and dimensions in accordance with the embodiments to provide a method and a structure in accordance with the invention, further in accordance with the accompanying claims.

What is claimed is:

1. A method for forming a structure comprising:
forming a doped aluminum oxide material layer upon a silicon material substrate; and
thermally annealing the doped aluminum oxide material layer formed upon the silicon material substrate to form a dopant depleted doped aluminum oxide material layer upon a silicon material substrate that includes a doped region.

2. The method of claim 1 wherein:
the doped aluminum oxide material layer comprises a p doped aluminum oxide material layer; and
the doped region comprises a p doped region.

3. The method of claim 1 wherein:
the doped aluminum oxide material layer comprises an n doped aluminum oxide material layer; and
the doped region comprises an n doped region.

4. The method of claim 1 wherein:
the doped aluminum oxide material layer comprises a p and n doped aluminum oxide material layer; and
the doped region comprises a p and n doped region.

5. A method for forming a structure comprising:
forming a boron doped aluminum oxide material layer upon a silicon material substrate; and
thermally annealing the boron doped aluminum oxide material layer formed upon the silicon material substrate to form a boron depleted boron doped aluminum oxide material layer upon a silicon material substrate that includes a boron doped region.

6. The method of claim 5 wherein the silicon material substrate comprises a silicon material selected from the group consisting of silicon, silicon-carbon alloy and silicon-germanium alloy silicon materials.

7. The method of claim 5 wherein the silicon material substrate comprises a monocrystalline silicon material substrate.

8. The method of claim 5 wherein the boron doped aluminum oxide material layer is formed using an atmospheric pressure chemical vapor deposition method.

9. The method of claim 5 wherein the boron doped aluminum oxide material layer is formed to a thickness from about 10 to about 40 nanometers.

10. The method of claim 5 wherein the boron doped aluminum oxide material layer includes a boron content from about 1 to about 25 atomic percent.

11. The method of claim 5 wherein the boron doped region has a sheet resistance from about 15 to about 300 ohms per square.

12. The method of claim 5 wherein the thermal annealing is undertaken at a temperature from about 800 to about 1100 degrees centigrade for a time period of about 15 to about 30 minutes.

13. The method of claim 5 further comprising forming a capping layer upon the boron doped aluminum oxide material layer prior to thermally annealing the boron doped aluminum oxide material layer.

14. A structure comprising:
a silicon material substrate;
a doped region located within the silicon material substrate; and
a doped aluminum oxide material layer located over the silicon material substrate and contacting the boron doped region, where the doped region and the doped aluminum oxide material layer comprise the same dopant.

15. The structure of claim 14 wherein:
the doped aluminum oxide material layer comprises a p doped aluminum oxide material layer; and
the doped region comprises a p doped region.

16. The structure of claim 14 wherein:
the doped aluminum oxide material layer comprises an n doped aluminum oxide material layer; and
the doped region comprises an n doped region.

17. The structure of claim 14 wherein:
the doped aluminum oxide material layer comprises a p and n doped aluminum oxide material layer; and
the doped region comprises a p and n doped region.

18. A structure comprising:
a silicon material substrate;
a boron doped region located within the silicon material substrate; and
a boron doped aluminum oxide material layer located over the silicon material substrate and contacting the boron doped region.

19. The structure of claim 18 wherein the silicon material substrate comprises a silicon material selected from the group consisting of silicon, silicon-carbon alloy and silicon-germanium alloy silicon materials.

20. The structure of claim 18 wherein the silicon material substrate comprises a monocrystalline silicon material.

21. The structure of claim 18 wherein the boron doped region has a sheet resistance from 15 to 300 ohms per square.

22. The structure of claim 18 wherein the boron doped region comprises a blanket boron doped region.

23. The structure of claim 18 wherein the boron doped region comprises a localized boron doped region.

24. The structure of claim 18 wherein the born doped aluminum oxide material layer has a thickness from about 10 to about 40 nanometers.

25. The structure of claim 18 further comprising a capping layer located upon the boron doped aluminum oxide material layer.
